(19) United States
(12) Patent Application Publication
(10) Pub. No.: US 2014/0368029 A1
(43) Pub. Date: Dec. 18, 2014

(54) SYSTEM FOR PROVIDING VEHICLE MANIPULATION DEVICE INFORMATION

(71) Applicant: HYUNDAI MOTOR COMPANY, Seoul (KR)

(72) Inventor: Beom Choon Park, Hwaseong (KR)

(73) Assignee: HYUNDAI MOTOR COMPANY, Seoul (KR)

(21) Appl. No.: 14/061,191

(22) Filed: Oct. 23, 2013

(30) Foreign Application Priority Data
Jun. 13, 2013 (KR) 10-2013-0067512

(51) Int. Cl. H03K 17/945

(52) U.S. Cl. CPC H03K 17/945
USPC 307/9.1

(57) ABSTRACT

A system for providing vehicle manipulation device information provides information about a manipulation device such as a switch or a button to a user in advance, before the user manipulates a device mounted on a vehicle, thus improving convenience in manipulation and driving stability. The system includes a proximity sensor installed in a manipulation portion having the manipulation device for manipulating the device mounted on the vehicle to sense an object that approaches the manipulation portion. The system also includes a controller that receives an approach sensing signal from the proximity sensor, and outputs a control signal for displaying manipulation device information of the manipulation portion, and a display unit for displaying the manipulation device information of the manipulation portion.

### CROSS-REFERENCE TO RELATED APPLICATION

This application claims under 35 U.S.C. §119(a) the benefit of Korean Patent Application No. 10-2013-0067512 filed on Jun. 13, 2013, the entire contents of which are incorporated herein by reference.

### BACKGROUND

(a) Technical Field

The present disclosure relates to a system for providing vehicle manipulation device information, and more particularly, to a system that provides information about a manipulation device such as a switch or a button to a user in advance, i.e., before the user manipulates a device mounted on a vehicle, thus improving convenience in manipulation and driving stability.

(b) Description of the Related Art

Given the remarkable progress in vehicle-related technology and electronic communication technology together with the rapid increase in the number of vehicles, there has been a growing demand of consumers toward more convenient, stable, and intelligent vehicles.

Various convenient devices, safety devices, and driving-assistance devices have been mounted on vehicles. For example, air-conditioning devices, audio/video (AV) systems, navigation systems for providing map information or traffic information, cruise control systems, information providing systems for providing video information, driver support information, vehicle information, and driving information, vehicle terminal devices, other types of driving-assistance systems and monitoring systems, and alert systems have been mounted on vehicles.

In addition, as application of new technology increases, the number of devices mounted on a vehicle and the number of types of the devices also increase, such that the number of manipulation devices, such as a switch and a button, the driver needs to manipulate during driving is also increasing.

Switches or buttons used frequently during driving of a vehicle may include a power window switch for opening and closing door glass, a side minor switch for manipulating an outside minor, an AV switch for manipulating an AV system, an air-conditioning switch, an emergency light switch, a center console switch (a seat heating cable switch or a transmission manipulation switch), an overhead console switch (a room lamp switch), a multifunction switch, and multiple switches installed on a left-hand lower portion of a crash pad and a steering wheel for manipulation of devices in the vehicle such as other lamps or AV systems.

Moreover, when new convenience devices, safety devices, and driving-assistance devices manipulated by switches are additionally used, the number of switches and the number of types of the switches also increase.

Generally, when a driver manipulates a switch while driving, a process of searching for a position of the switch, a process of manipulating the switch, a process of checking the current manipulation position and manipulation state after manipulation, a process of re-manipulating the switch for desired manipulation position and manipulation state, and a process of checking the re-manipulation position and re-manipulation state are required.

Conventionally, only when a switch installed on a vehicle is pressed, a corresponding function is executed, the execution result is displayed, and the switch is identified.

In particular, during manipulation, the driver needs to watch manipulation devices (a button, a switch, a knob, a dial, a lever, and so forth) distributed in the vehicle and a display showing a manipulation state while taking eyes off the front of the vehicle, thus failing to concentrate in the driving.

As a result, during manipulation, if an emergency situation occurs such as when an obstacle suddenly appears in front of the vehicle or another vehicle in front of the vehicle suddenly stops, prompt action may be impossible, and because the driver does not keep eyes forward, a very dangerous situation such as vehicle collision, line departure, or crossing of the center line may occur and the risk of a vehicle accident highly increases, potentially endangering the driver and others.

Moreover, since manipulation portions in which switches are installed are distributed in a door, a center facia, a center console, an overhead console, a crash pad left-hand lower portion, and a steering wheel, if the driver moves view to find out a position of the switch, there is a high risk of a big accident and due to a change in the driver's posture, instability of handling (unconscious handling manipulation due to the posture change and erroneous manipulation of steering wheel due to one-hand manipulation) is caused.

In comparison to when the driver acquires information while viewing an information display device located in front of the driver's seat, for example, a cluster, a Headup Display (HUD), an AV system, or a navigation system, during driving, when the driver views a door inner side, a center facia, or a center console, the driver has to move the eyes far away, increasing the probability of occurrence of an accident and the level of the risk.

### SUMMARY

Accordingly, the present invention is directed to a system for providing vehicle manipulation device information, which provides information about a manipulation device such as a switch or a button to a user in advance, i.e., before the user manipulates a device mounted on the vehicle, thereby improving convenience in manipulation and driving stability.

According to an aspect of the present invention, there is provided a system for providing manipulation device information, the system including a proximity sensor installed in a manipulation portion having a manipulation device for manipulating a device mounted on a vehicle to sense an object that approaches the manipulation portion, a controller for, upon receiving an approach sensing signal from the proximity sensor, outputting a control signal for displaying manipulation device information of the manipulation portion, and a display unit for displaying the manipulation device information of the manipulation portion according to the control signal of the controller.

The manipulation portion may include a single manipulation device or a plurality of manipulation devices which are disposed in adjacent to each other to share one proximity sensor that senses the approach of the object.

If the manipulation portion includes the plurality of manipulation devices, the manipulation devices included in the manipulation portion are grouped, such that the proximity sensor is installed for each manipulation device group.

The display unit is one or more of a Headup Display (HUD), a cluster, and a display device of a vehicle terminal device.

The system may further include a touch sensor separately installed in each manipulation device of the vehicle to sense a hand touch of the user, in which upon receiving a hand touch sensing signal of the touch sensor, the controller controls driving of the display unit to display information of the manipulation device in which the touch sensor is installed.

### BRIEF DESCRIPTION OF THE DRAWINGS

The above and other features of the present invention will now be described in detail with reference to an exemplary embodiment thereof illustrated the accompanying drawings which are given hereinbelow by way of illustration only, and thus are not limitative of the present invention, and wherein:

FIG. 1 is a block diagram illustrating a system for providing manipulation device information according to an embodiment of the present invention;

FIG. 2 is a perspective view illustrating an installation position of a proximity sensor in the system for providing manipulation device information of FIG. 1;

FIG. 3 is a perspective view illustrating an installation state of the proximity sensor of FIG. 2;

FIG. 4 is a conceptual diagram illustrating a structure and an operation scheme of the proximity sensor of FIG. 2; and

FIG. 5 is an installation state diagram illustrating a touch sensor of each switch in the system for providing manipulation device information of FIG. 1.

### DETAILED DESCRIPTION

Hereinafter, the present invention will be described in detail with reference to the accompanying drawings to allow those of ordinary skill in the art to easily carry out the present invention.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The present invention relates to an information providing system for reducing the risk of an accident originating from device manipulation during driving of a vehicle and improving driving stability of operation by a driver, and more particularly, to a system that provides information about a manipulation device such as a switch or a button in advance to a user prior to manipulation of a device mounted on the vehicle (hereinafter, a vehicle device), thus improving manipulation convenience and driving stability.

The system for providing manipulation device information according to the present invention is configured to display various information about manipulation devices, such as information about a function of a manipulation device (information about an associated vehicle device and switch function information), information about a current manipulation state (an operation state of a vehicle device), and an operation performed in manipulation through a display unit such as a cluster, a Headup Display (HUD), or a navigation/AV monitor.

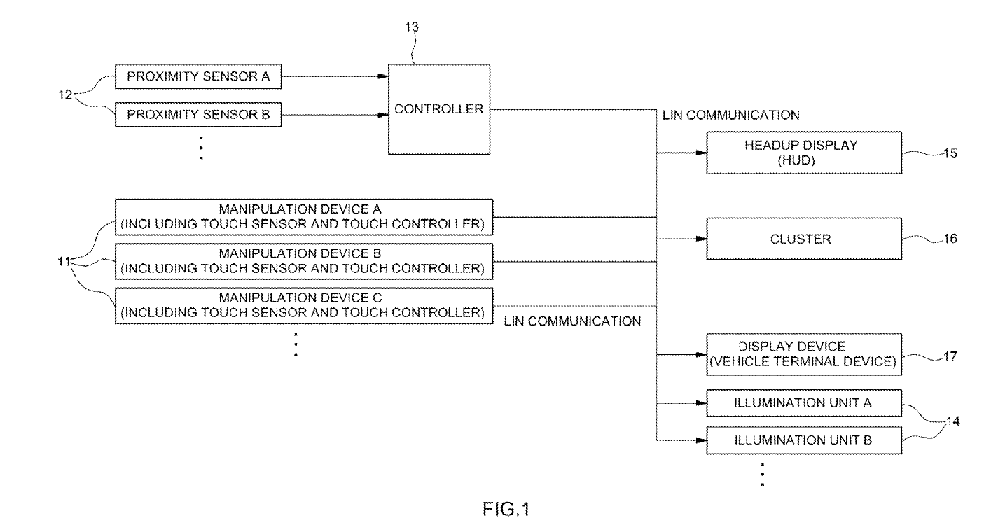

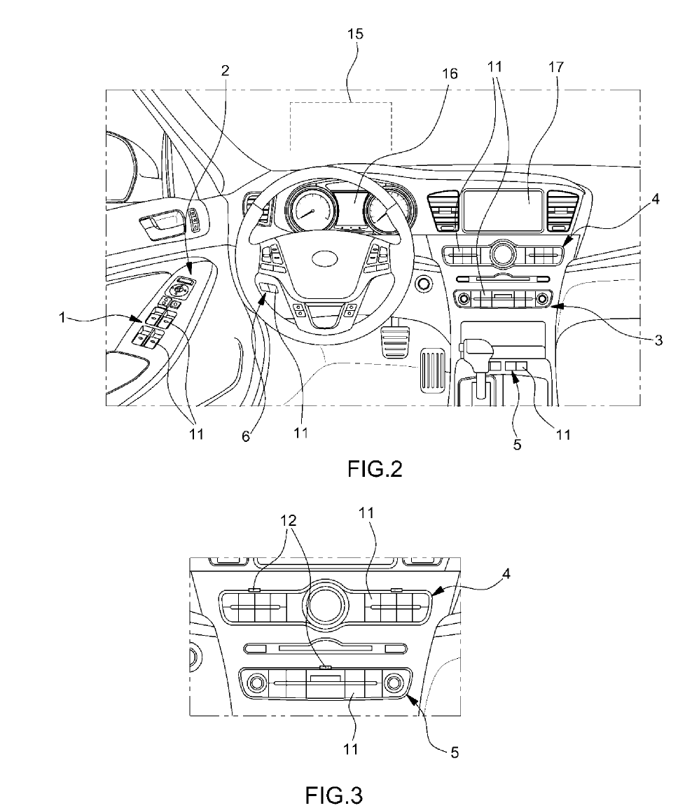

FIG. 1 is a block diagram illustrating a structure of an apparatus for providing manipulation device information according to an embodiment of the present invention. FIG. 2 is a perspective view illustrating an installation position of a proximity sensor for use in the apparatus. FIG. 3 is a perspective view illustrating an installation state of the proximity sensor.

A system for providing manipulation device information according to the present invention includes a proximity sensor 12 which is installed in each of manipulation portions 1-6 in predetermined positions of a vehicle to sense an object that approaches the manipulation portions 1-6, a controller 13 for receiving an approach sensing signal of the proximity sensor 12 to output a control signal for displaying related information of a manipulation device 11 in the manipulation portions 1-6 where the proximity sensors 12 are positioned, and display units 15-17 for displaying related information of a manipulation device in a manipulation portion to which the approach of an object is sensed by the proximity sensor 12 according to the control signal of the controller 13.

In the present invention, the manipulation device 11 may be a switch, a button, a knob, a dial, or a lever installed in a predetermined position in the vehicle for use in manipulation of a vehicle device, and any manipulation means may be a manipulation device if it is installed for manipulation of a vehicle device.

In the present invention, the manipulation portions 1-6 include the manipulation device 11 and refer to predetermined portions in the vehicle in which the manipulation device 11 used by a driver or a passenger to manipulate a vehicle device is installed. In particular, as used herein, the term “manipulation portions” refers to one or a plurality of manipulation portions, where these manipulation portions are exemplified by reference numbers 1 to 6 in FIG. 2, for example. However, one of ordinary skill in the art would understand that the manipulation portions depicted in the drawings are merely for illustration purposes, and it is possible to provide only a single manipulation portion, or additional manipulation portions, depending on the vehicle design.

The manipulation portions 1-6 may have one manipulation device (a switch or a button) 11 or a plurality of manipulation devices, and one proximity sensor 12 may be installed in each of them, or manipulation devices in each manipulation portion may be grouped and a proximity sensor may be installed for each manipulation device group. In particular, a plurality of proximity sensors 12 may be installed in each manipulation portion 1-6, and in this case, the proximity sensor 12 senses an object such as a user's hand that approaches one manipulation device 11 or a plurality of manipulation devices. Each proximity sensor 12 senses the approach of an object to a manipulation device in a manipulation portion for each manipulation device 11 or each manipulation device group in each of the manipulation portions 1-6.

In the present invention, the proximity sensor 12 may be installed in a primary position in the vehicle where the manipulation device 11 such as a switch or a button is installed, and senses an object that approaches the manipulation device 11 to deliver an electric signal (approach sensing signal) to the controller 13.

Generally, in a vehicle, various switches or buttons for manipulating the same vehicle device and switches or buttons that are related to each other for a function of the device are grouped in each designated manipulation portion region in the vehicle for convenience in user manipulation. Therefore, when the proximity sensor 12 is installed for each group including the plurality of manipulation devices 11, the plurality of manipulation devices used for manipulating the same device or manipulation devices that are related to each other for a function of the device may be grouped and the proximity sensor 12 may be installed for each group. In addition, if information about several manipulation devices may be classified and simultaneously displayed on one screen to allow the user to easily and conveniently recognize them, such manipulation devices may be grouped as the same group.

However, when one proximity sensor 12 senses the approach of an object to the several manipulation devices 11, if the user's hand approaches manipulation devices in a designed sensing region, a single proximity sensor 12 needs to sense the approach of the object to the manipulation devices in the sensing region. Thus, the manipulation devices to be sensed by one proximity sensor 12, that is, the manipulation devices that share one proximity sensor 12, should be disposed in adjacent to one another in the same manipulation portion 1-6.

Moreover, as described herein, the plurality of proximity sensors 12 may be installed in one manipulation portion 1-6, or one proximity sensor 12 may be installed in one manipulation device 11. Alternatively, one proximity sensor 12 may be installed in a group of the plurality of manipulation devices 11.

FIGS. 2 and 3 are diagrams illustrating a position in which a proximity sensor (not shown in FIG. 2) is installed, in which the proximity sensor is installed for each of the predetermined manipulation portions 1-6 having a plurality of manipulation devices (a switch, a button, a knob, a dial, and a lever) 11.

For example, when power window switches for manipulating door glass and side mirror switches for manipulating an outside mirror are installed in a door inner side, one proximity sensor or a plurality of proximity sensors may be installed for every two manipulation portions, that is, for each power window switch 1 and side mirror switch 2.

One proximity sensor 12 or a plurality of proximity sensors 12 may be installed in each of an AV switch unit 3 having manipulation devices (switches, buttons, or knobs) for manipulating each manipulation portion, for example, an AV system, provided in the center facia and an air-conditioning switch unit 4 having manipulation devices for manipulating an air-conditioning device (see FIG. 3).

As other manipulation portions in which a proximity sensor is installed, a center console switch unit 5 including the manipulation devices 11 installed in front of a console box, around a cup holder in front of the console box, and in a tray in front of the console box and a crash pad left-hand lower switch unit 6 in which various manipulation devices for manipulating other vehicle devices are installed may be further provided. Although not shown in the drawings, switches for manipulating a room lamp are also installed around an overhead console near a loop panel, such that a proximity sensor may also be installed in an overhead console switch unit including such switches.

When the user hand approaches the manipulation device 11 within a predetermined sensing region, each proximity sensor 12 may have to sense the approach and output an electric sensing signal. Thus, the installation position of the proximity sensor 12 in the manipulation portion may be a position around the manipulation device 11 which permits sensing of the user hand when the user hand is in a position that may cover the manipulation device 11 in the sensing region or approaches the manipulation device 11 within a predetermined distance from the manipulation device 11.

Referring to FIG. 3, each proximity sensor 12 is installed around the manipulation device 11 such as a switch or a button in the AV switch unit 3 for AV system manipulation and the air-conditioning switch unit 5 for manipulation of an air-conditioning device.

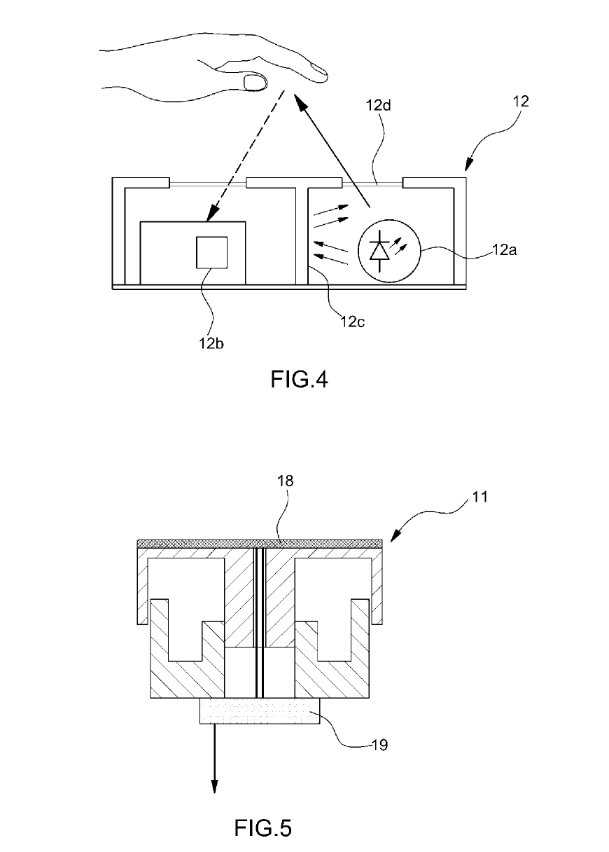

FIG. 4 is a conceptual diagram illustrating a structure and an operation scheme of a proximity sensor that is applicable to a system for providing manipulation device information according to an embodiment of the present invention, in which a proximity sensor of a reflected light detection type may be used as the proximity sensor in the present invention and as the proximity sensor of the reflected light detection type, an infrared proximity sensor may be preferably used. The proximity sensor 12 of the reflected light detection type includes a light-emitting unit 12a for emitting light (infrared light), a light-receiving unit 12b for receiving light reflected and coming back from an approaching object, and an electric circuit unit (not shown) for outputting an electric signal indicating sensing of the approach based on the light received by the light-receiving unit 12b when the object approaches. The light-emitting unit 12a may include a light-emitting diode for emitting light, and the light emitted from the light-emitting diode is reflected through a reflection mirror 12c and then is collected to pass through a front window 12d. When the user moves his or her hand near the manipulation device for manipulation, the light emitted from the light-emitting unit 12a is reflected from the user's hand and is received by the light-receiving unit 12b, and the electric circuit unit outputs an approach sensing signal based on the light received by the light-receiving unit 12b.

Once the controller 13 receives the access sensing signal, the controller 13 controls driving of the display units 15-17 to display information about the manipulation device 11 in which the proximity sensor 12 is installed (in case of one proximity sensor for one manipulation device) or a manipulation device group. If the controller 13 receives the approach sensing signal from the proximity sensor 12, the manipulation device 11 or the manipulation device group for which the approach of an object is sensed by the corresponding proximity sensor is recognized, and then the stored display information is delivered, such that a control signal for displaying the display information through the display units 15-17 is output.

In the present invention, the display unit may be the HUD 15 or the cluster, or the display device 17 of a vehicle terminal device such as a navigation system/AV monitor. The cluster 16 may include a separate display device implemented with an LCD or the like, and in particular, the display device of the cluster is a display unit for displaying information about the manipulation device in the present invention. In this state, when the approach of the user hand is sensed, the function of the manipulation device 11 or the manipulation device group may be displayed through the HUD 15 or the cluster 16.

Through the display device 17 of the vehicle terminal device, in addition to the display information displayed through the HUD 15 or the cluster 16, some or all of related information such as the current operation state (manipulation state and manipulation position), function, and expected operation state in manipulation of the device related to the manipulation device 11 or the manipulation device group (vehicle device manipulated by the manipulation device) may be displayed.

The cluster, the HUD, and the vehicle terminal device have separate controllers for controlling their operations, such that an actual information display operation may be performed by communication between the controller 13 configured to receive the approach sensing signal of the proximity sensor 12 and the controller of the cluster/HUD/vehicle terminal device (for example, connection between the controllers through LIN communication may be possible).

Instead of separate controllers for directly receiving the approach sensing signal of the proximity sensor 12, the controller of the cluster/HUD/vehicle terminal device may directly receive the approach sensing signal of the proximity sensor 12 and may control driving of the display unit to display related information of the manipulation device 11, and such a configuration is also included in the scope of the present invention.

In the present invention, the controller 13 may be set to increase the illumination brightness of the manipulation device 11 in which the proximity sensor 12 is installed, upon receiving the approach sensing signal of the proximity sensor 12.

For example, as illustrated in FIG. 1, for each manipulation device (switch) 11 or each manipulation device group which shares the proximity sensor 12, an illumination unit 14 that operates according to a control signal of the controller 13 is provided, and when the user hand approaches the illumination unit 14 for manipulation, the proximity sensor 12 senses the approach and inputs the approach sensing signal to the controller 13. Then, the controller 13 increases the brightness of the illumination unit 14 of the manipulation device 11 or the manipulation device group (increases the intensity of light), thus improving visibility in night-time manipulation.

The illumination unit may be installed directly in the manipulation device or in the periphery of the manipulation device, and when a manipulation device group including a plurality of manipulation devices disposed in adjacent to each other to share one proximity sensor is provided, a separate illumination unit for each manipulation device group may be installed.

When the driver drives the vehicle in a very dark indoor condition of the vehicle, the user may not easily recognize the position of the manipulation device, such that by taking the hand near the manipulation device, the illumination unit 14 in the corresponding position may be brightened, thus facilitating the visibility of the manipulation device 11.

Meanwhile, the system for providing manipulation device information according to the present invention may further include a touch sensor 18 which is separately installed for each manipulation device 11, for example, for each switch, to sense a touch by the user hand.

FIG. 5 is an installation state diagram illustrating a touch sensor of each switch in the system for providing manipulation device information according to an embodiment of the present invention, in which the touch sensor 18 is installed on a front surface or a side surface of the manipulation device (for the knob or the dial) that is a hand contact surface when the user manipulates the manipulation device 11, and a type of the touch sensor 18 is preferably a capacitance-type touch sensor.

When the touch sensor 18 senses the user hand touch, the touch sensor 18 outputs an electric signal, that is, a touch sensing signal, and the controller receives the touch sensing signal output by the touch sensor 18. Herein, the controller may be the same as the controller 13 for receiving an electric signal, that is the approach sensing signal, output from the proximity sensor 12 or may be a separately provided controller which may be a controller 19 (indicated by ‘touch controller’ in FIG. 1) that is separately installed for each manipulation device.

In the present invention, the plurality of controllers may be connected or the controller and the display unit may be connected to exchange signals and information therebetween through vehicle network communication (for example, LIN communication).

The manipulation device 11 in which the touch sensor 18 is installed is not limited to the manipulation device in which the proximity sensor 12 is installed, and it may also be possible that only the touch sensor 18 may be installed in a separate manipulation device even if the proximity sensor 12 is not installed therein.

An example of the manipulation device in which only the touch sensor is installed may be an emergency light lamp switch.

Thus, if the user hand touch is sensed by the touch sensor 18 in each manipulation device 11, the controller 19 controls driving of the display units 15-17 to display related information of a separate manipulation device, and in this case, previously stored information of the separate manipulation device is transmitted to the display unit for display on the screen. In this case, through the HUD 15, the function or name of the touched manipulation device 11 may be displayed and through the display information, the driver may recognize the manipulation device the user touches by the hand.

Through the cluster 16, the function or name of the touched manipulation device 11 may be displayed and information such as the current manipulation state of the manipulation device 11 (that is, the current operation state of the related device) may be displayed.

Through the display device 17 of the vehicle terminal device, in addition to the information displayed through the HUD 15 or the cluster 16, some or all of information such as expected operation state and executed function of the manipulation device 11 in manipulation of the manipulation device 11 may be displayed in more detail.

In this way, in the system for providing the information according to the present invention, if the user such as the driver or the passenger takes the hand to the manipulation portion region (sensing region), the proximity sensor 12 senses the approach of the hand and displays related information of the manipulation device group (information about the manipulation device and the related device, the manipulation state and manipulation position, and device operation information) through the display units 15-17.

Next, if the user touches the manipulation device 11 by the hand, the touch sensor 18 senses the touch and related detail information of the corresponding manipulation device (information about the name and function of the separate manipulation device, related device information, information about the current operation state of the device, and information about an expected operation state of the device in manipulation) is displayed through the display units 15-17.

Once the user manipulates the manipulation device 11, the corresponding function is executed.

In this process, if the approach of the hand is sensed by the proximity sensor 12 or the hand touch is sensed by the touch sensor 18, the manipulation device-related display information displayed through the display units 15-17 may be displayed by transmission of information stored for the manipulation device 11 by the controllers 13 and 19, and the controller may transmit the current manipulation state and manipulation position of the manipulation device and the operation state information of the related device to the display unit before and after manipulation of the manipulation device for display through the display unit.

As such, the system for providing information according to the present invention facilitate user convenience in use of the manipulation device such as a switch, and especially, in manipulating the manipulation device by the driver during driving and recognizing information the vehicle state information.

In addition, when the driver may find out a desired switch without moving the view for manipulation of the switch while keeping the eyes forward during driving, and may easily find out the switch of the desired device through the proximity sensor without touching the separate switch by the hand, thereby improving productivity, convenience in manipulation of the vehicle device, and the safety of driving.

Hence, with the system for providing vehicle manipulation device information according to the present invention, the user may easily and conveniently use the manipulation device such as the switch, and particularly, convenience and safety in manipulating the manipulation device during driving and recognizing vehicle state information are provided.

While the embodiment of the present invention has been described in detail, the scope of the present invention is not limited to the foregoing embodiment and various modifications and improves made by those of ordinary skill in the art using the basic concept of the present invention defined in the appended claims are also included in the scope of the present invention.

What is claimed is:

1. A system for providing vehicle manipulation device information, the system comprising:
a proximity sensor installed in a manipulation portion having a manipulation device for manipulating a device mounted on a vehicle to sense an object that approaches the manipulation portion;
a controller for, upon receiving an approach sensing signal from the proximity sensor, outputting a control signal for displaying manipulation device information of the manipulation portion; and
a display unit for displaying the manipulation device information of the manipulation portion according to the control signal of the controller.

2. The system of claim 1, wherein the manipulation portion comprises a single manipulation device or a plurality of manipulation devices which are disposed adjacent to each other to share one proximity sensor that senses the approach of the object.

3. The system of claim 2, wherein if the manipulation portion comprises the plurality of manipulation devices, the manipulation devices included in the manipulation portion are grouped, such that the proximity sensor is installed for each manipulation device group.

4. The system of claim 1, wherein a plurality of manipulation portions disposed in predetermined positions of the vehicle are provided, and the proximity sensor is installed for each manipulation portion.

5. The system of claim 1, wherein the proximity sensor is of a reflected-light detection type which comprises a light-emitting unit for emitting light, a light-receiving unit for receiving light reflected from an approaching object, and an electric circuit unit for outputting an approach sensing signal based on the light received by the light-receiving unit.

6. The system of claim 5, wherein the proximity sensor is an infrared proximity sensor which emits and receives infrared light.

7. The system of claim 1, wherein the display unit is one or more of a Headup Display (HUD), a cluster, and a display device of a vehicle terminal device.

8. The system of claim 7, wherein the HUD and the cluster are configured to display information comprising function information of the manipulation device in the manipulation portion to which the approach of the object is sensed.

9. The system of claim 7, wherein the display device of the vehicle terminal device is configured to display any one of function information of the manipulation device in the manipulation portion to which the approach of the object is sensed, information about the device that may be manipulated by the manipulation device, current operation state information of the device, and expected operation state information of the device in manipulation.

10. The system of claim 1, further comprising:
a touch sensor separately installed in each manipulation device of the vehicle to sense a hand touch of the user,
wherein upon receiving a hand touch sensing signal of the touch sensor, the controller controls driving of the display unit to display information of the manipulation device in which the touch sensor is installed.

11. The system of claim 10, wherein the touch sensor is of a capacitance type that is installed on a hand contact surface of the manipulation device in manipulation.

12. The system of claim 10, wherein the display unit is one or more of the HUD, the cluster, and the display device of the vehicle terminal device.

13. The system of claim 12, wherein the HUD displays a function or a name of the manipulation device whose touch by the hand is sensed, and the cluster displays the current operation state of the device that may be manipulated by the manipulation device, together with the function or the name of the manipulation device whose touch by the hand is sensed.

14. The system of claim 12, wherein the display device of the vehicle terminal device displays information about one or more of a function or a name of the manipulation device whose touch by the hand is sensed, a current operation state of the device that may be manipulated by the manipulation device, and an expected operation state of the manipulation device or an executed function of the manipulation device in manipulation.

15. The system of claim 1, further comprising an illumination unit installed in the manipulation device or in the periphery of the manipulation device to operate according to the control signal of the controller, wherein upon receiving the approach sensing signal from the proximity sensor, the controller increases the illumination brightness of the illumination unit to secure the visibility of the manipulation device.

16. The system of claim 15, wherein if a plurality of manipulation devices disposed in adjacent to each other form a manipulation device group to share one proximity sensor, a separate illumination unit is installed for each manipulation device group.

17. A vehicle comprising:
a system for providing vehicle manipulation device information, the system comprising:
a proximity sensor configured to sense an object that approaches a manipulation portion;
a controller for, upon receiving an approach sensing signal from the proximity sensor, outputting a control signal for displaying manipulation device information of the manipulation portion; and
a display unit for displaying the manipulation device information of the manipulation portion according to the control signal of the controller.

18. The vehicle of claim 17, wherein the manipulation portion comprises a single manipulation device or a plurality of manipulation devices which are disposed adjacent to each other to share one proximity sensor that senses the approach of the object.

19. The vehicle of claim 18, wherein if the manipulation portion comprises the plurality of manipulation devices, the manipulation devices included in the manipulation portion are grouped, such that the proximity sensor is installed for each manipulation device group.

20. The vehicle of claim 17, wherein a plurality of manipulation portions disposed in predetermined positions of the vehicle are provided, and the proximity sensor is installed for each manipulation portion.
